(19) United States
(12) Patent Application Publication
(10) Pub. No.: US 2026/0120992 A1
(43) Pub. Date: Apr. 30, 2026

(54) ENERGY MEASUREMENT SYSTEM AND METHOD OF ENERGY MEASUREMENT IN LINEAR ACCELERATOR

(71) Applicant: Applied Materials, Inc., Santa Clara, CA (US)

(72) Inventor: Keith E. Kowal, Swampscott, MA (US)

(73) Assignee: Applied Materials, Inc., Santa Clara, CA (US)

(21) Appl. No.: 18/926,739

(22) Filed: Oct. 25, 2024

(51) Int. Cl. H01J 37/244; H01J 37/317

(52) U.S. Cl. CPC H01J 37/244; H01J 37/3171

(57) ABSTRACT

An ion implanter. The ion implanter may include an ion source to generate a continuous ion beam, and a linear accelerator to receive generate a bunched ion beam from the continuous ion beam, and accelerate the bunched ion beam. The linear accelerator may include a plurality of acceleration stages, arranged to accelerate the bunched ion beam to a plurality of energy levels, respectively, and a beam energy measurement system, arranged to measure a beam energy of the bunched ion beam, after exiting at least one of the plurality of acceleration stages. As such, the beam energy measurement system may include a fingerprint signal generation circuit, to impart a fingerprint signal into an RF signal to an acceleration stage of the linear accelerator, and a fingerprint detection circuit, disposed downstream of the acceleration stage, and arranged to detect the fingerprint signal.

### FIELD OF THE DISCLOSURE

The disclosure relates generally to ion implantation apparatus and more particularly to high energy beamline ion implanters based upon linear accelerators.

### BACKGROUND OF THE DISCLOSURE

Ion implantation is a process of introducing dopants or impurities into a substrate via bombardment. Ion implantation systems may comprise an ion source and a series of beam-line components. The ion source may comprise a chamber where ions are generated. One type of ion implanter suitable for generating ion beams of medium energy and high energy uses a linear accelerator, or LINAC, where a series of electrodes arranged as tubes around the ion beam are provided to accelerate the ion beam to increasingly higher energy along the succession of tubes. The various electrodes may be arranged in a series of stages where a given electrode in a given stage receives an AC voltage signal, an in particular, a radio frequency voltage (RF voltage) to accelerate the ion beam.

RF LINACs (generally referred to herein as “LINACs”) employ initial portions of the LINAC as so-called buncher(s) that bunch an initially-continuous ion beam into a bunched ion beam. A given acceleration stage of the LINAC is used to increase ion energy by accelerating bunched ions using, for example, a resonator generating an RF voltage that is applied to a given electrode or set of electrodes at the given stage. The RF voltage generates an oscillating electric field that is coupled into an ion beam being conducted through the LINAC by controlling the phase and amplitude of the RF voltage applied to the given LINAC stage.

In known systems, the ion energy of a bunched ion beam may be measured, for example, after exiting a LINAC by measuring the so-called time of flight (TOF) of an ion bunch. TOF measurements may be performed, for example, by a pair of detectors that are positioned with a certain separation distance along the direction of propagation of a bunched ion beam. By determining the time interval between detection of an ion bunch at a first detector and detection of the ion bunch at a second detector, the ion velocity may be determined, given knowledge of the separation between detectors, and hence the ion energy may be calculated given the ion mass. Such TOF ‘beam sensor’ systems may employ capacitive detectors or inductive detectors, adding more hardware to an ion implanter beamline. Additionally, more signal processing is needed to calculate ion energy from the raw signals generated by the beam sensor TOF systems.

With respect to these and other considerations, the present disclosure is provided.

### BRIEF SUMMARY

In one embodiments, an ion implanter is provided. The ion implanter may include an ion source to generate a continuous ion beam, and a linear accelerator to receive generate a bunched ion beam from the continuous ion beam, and accelerate the bunched ion beam. The linear accelerator may include a plurality of acceleration stages, arranged to accelerate the bunched ion beam to a plurality of energy levels, respectively, and a beam energy measurement system, arranged to measure a beam energy of the bunched ion beam, after exiting at least one of the plurality of acceleration stages. As such, the beam energy measurement system may include a fingerprint signal generation circuit, to impart a fingerprint signal into an RF signal to an acceleration stage of the linear accelerator, and a fingerprint detection circuit, disposed downstream of the acceleration stage, and arranged to detect the fingerprint signal.

In another embodiment, a method of operating an ion implanter is provided. The method may include generating a continuous ion beam, and bunching the continuous ion beam into a bunched ion beam. The method may further include accelerating the bunched ion beam in a linear accelerator that comprises a plurality of acceleration stages. The method may include generating a fingerprint signal at a first instance, for coupling to an acceleration stage of the linear accelerator; and detecting the fingerprint signal at a second instance, at a detection location, downstream to the acceleration stage.

### BRIEF DESCRIPTION OF THE DRAWINGS

FIG. 1A shows an exemplary ion implantation system, according to embodiments of the disclosure;

FIG. 1B shows an exemplary acceleration stage of a linear accelerator;

FIG. 1C shows an exemplary controller;

FIG. 2A illustrates one exemplary architecture for beam energy measurement;

2B show an exemplary fingerprint;

FIG. 3 shows details of an exemplary fingerprint signal generation arrangement;

FIG. 4 shows details of an exemplary beam energy measurement system; and

FIG. 5 depicts an exemplary process flow according to some embodiments of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved linear accelerator control, and improved high energy ion implantation systems, based upon a beamline architecture using a linear accelerator (LINAC). For brevity, an ion implantation system may also be referred to herein as an “ion implanter.” Various embodiments provide novel configurations for providing the capability of generating high energy ions, where the final ion energy delivered to a substrate may be 300 keV, 500 keV, 1 MeV or greater. In exemplary embodiments, a novel beam energy measurement arrangement and techniques are provided for determining ion beam energy in a LINAC.

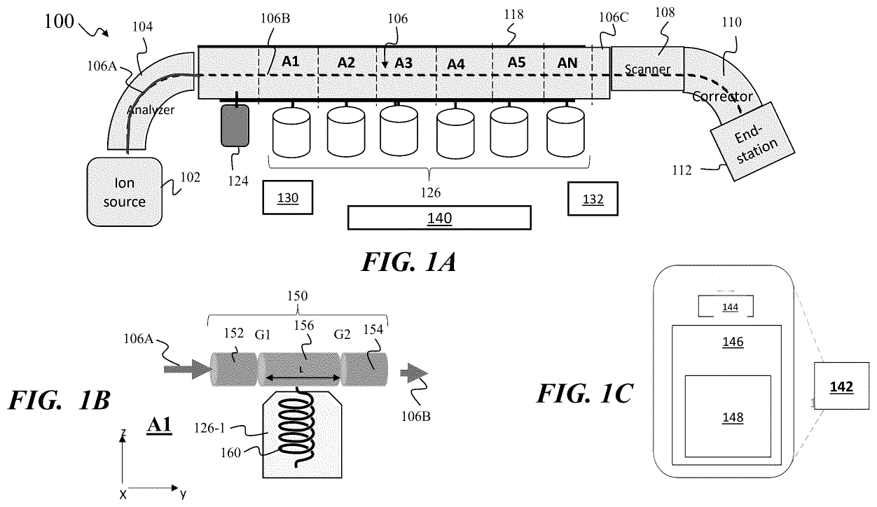

FIG. 1A depicts a schematic of an ion implanter apparatus, according to embodiments of the disclosure. The ion implanter 100, may represent a beamline ion implanter, with some elements not shown for clarity of explanation. The ion implanter 100 may include an ion source 102, as known in the art. The ion source 102 may include an extraction system including extraction components and filters (not shown) to generate an ion beam 106 at a first energy. Examples of suitable ion energy for the first ion energy range from 5 keV to 300 keV, while the embodiments are not limited in this context. To form a high energy ion beam, the ion implanter 100 may include various additional components for accelerating the ion beam 106. As output by the ion source 102, the ion beam may be a continuous ion beam 106A.

The ion implanter 100 may include an analyzer 104, functioning to analyze the ion beam 106 as in known apparatus, by changing the trajectory of the ion beam 106, as shown. The ion implanter 100 may also include a buncher 124, which component may form an upstream part of an RF linear accelerator, shown as LINAC 118. The buncher 124 may be arranged as in known apparatus to output the continuous ion beam 106A as a bunched ion beam 106B. The LINAC 118 may include various acceleration stages to accelerate the bunched ion beam 106B by application of an RF signal at the different stages. The LINAC may output the bunched ion beam 106B as a high energy ion beam 106C. The ion implanter 100 may include various additional components, such as a scanner 108, to scan the high energy ion beam 106C, such as in a transverse direction to a direction of propagation of the high energy ion beam 106C. The ion implanter may further include components such as a corrector 110 and end station 112, as known in the art.

To impart a target final energy to the high energy ion beam 106C, the LINAC 118 may include a series of RF assemblies, where a given RF assembly is arranged to deliver a given RF signal to a given acceleration stage of the LINAC 118. The different acceleration stages of LINAC 118 are identified as acceleration stage A1, acceleration stage A2, acceleration stage A3, acceleration stage A4, acceleration stage A5, and acceleration stage AN. However, according to other embodiments, the LINAC 118 may have fewer acceleration stages or a greater number of acceleration stages, where the acceleration stage AN may represent the last, most downstream acceleration stage that outputs the high energy ion beam 106C at a highest beam energy. A given acceleration stage of the acceleration stages of LINAC 118 may be coupled to a dedicated RF assembly that includes an RF power source (not separately shown) that generates an RF signal to power the given acceleration stage. The RF signal is fed to a resonator circuit, or “resonator,” which circuit couples an RF voltage to an electrode in the given acceleration stage, as detailed with respect to FIG. 1B. These resonator circuits are designated as resonators 126 in FIG. 1A. As the bunched ion beam 106B passes through successive acceleration stages of the LINAC 118, the bunched ion beam 106B will be accelerated to a high energy, based upon the number of acceleration stages and the amplitude of the RF voltage applied by a given resonator 126 at each acceleration stage.

To illustrate how energy is coupled into a bunched ion beam, FIG. 1B depicts details of an exemplary acceleration stage, shown as acceleration stage A1, which stage may be representative of any of the acceleration stages (A1-AN) shown in FIG. 1A. The acceleration stage A1 may include a drift tube assembly 150, as well as a resonator 126-1. In various non-limiting embodiments the drift tube assembly 150 may be a double gap configuration or a triple gap configuration. The configuration explicitly shown in FIG. 1B is a double gap configuration. In this arrangement, the drift tube assembly 150 includes a first grounded drift tube 152, a second grounded drift tube 154, and a powered drift tube 156. As suggested, the first grounded drift tube 152 and the second grounded drift tube 154 may be coupled to ground potential. The powered drift tube 156 is coupled to a resonator coil 160 that delivers an RF voltage signal, which RF voltage signal causes an RF field to develop in the gap G1 between the first grounded drift tube 152 and the powered drift tube 156, as well as an RF field in the gap G2 between the powered drift tube 156 and the second grounded drift tube 154. The timing of the phase of an RF signal as applied to the powered drift tube 156 will affect how an ion bunch that passes through gap G1 or gap G2 is accelerated by the acceleration stage.

Referring again to FIG. 1A, in order to measure the beam energy of a bunched ion beam, in the present approach, the ion implanter 100 is provide with a fingerprint signal generation circuit 130, and a fingerprint detection circuit 132, as well as control system 140. In brief, the fingerprint signal generation circuit is arranged to impart a fingerprint signal into an RF signal that is generated by a given RF assembly for a given acceleration stage of the LINAC 118. The fingerprint detection circuit 132 is arranged downstream to the acceleration stage that receives the fingerprint signal, and is arranged to detect the fingerprint signal after generation of the fingerprint signal. As detailed with the embodiments to follow, with knowledge of the time interval between the instance of fingerprint signal generation and the instance of fingerprint signal detection, as well as the distance between location of the generation of the fingerprint signal and location of the detection of the fingerprint signal, the beam velocity and therefore beam energy of the bunched ion beam 106B may be determined.

Some details of the control system 140 are provided in FIG. 1C, with the operation described further below.

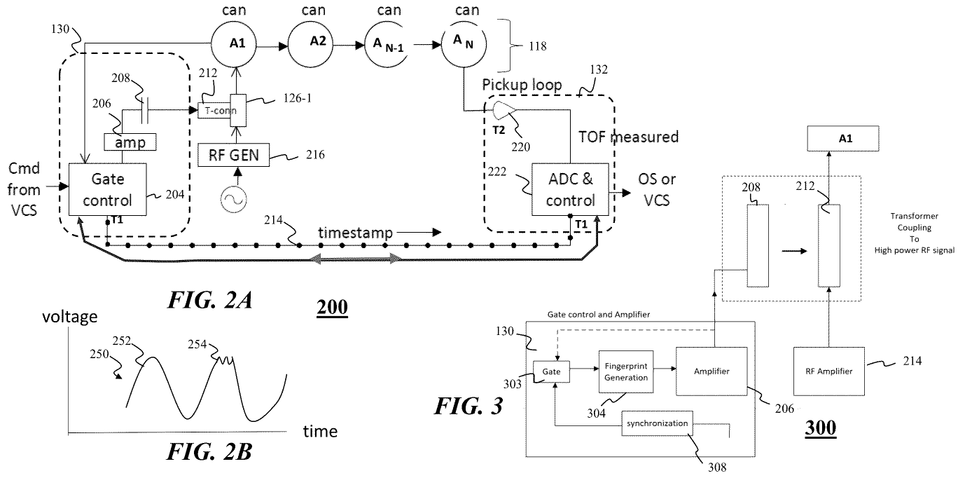

FIG. 2 illustrates one exemplary architecture for beam energy measurement. The arrangement 200 depicts a portion of an embodiment of the ion implanter 100, including the LINAC 118. One variant of the fingerprint signal generation circuit 130 is shown, as well as a variant of the fingerprint detection circuit 132. Together the circuits may be deemed to constitute at least part of a beam energy measurement system that is to measure the beam energy of a bunched ion beam traversing the LINAC 118.

In FIG. 2A, the fingerprint signal generation circuit 130 includes a gate control and synchronization circuit 204 that is coupled to an amplifier 206, capacitor 208, and transformer 212. The fingerprint signal generation circuit 130 may generate a fingerprint signal that is coupled into an RF signal generated by RF assembly 216 and transmitted to an acceleration stage of the linear accelerator for accelerating a bunched ion beam. In this example, the RF assembly is coupled to acceleration stage A1, via resonator 126-1. The fingerprint signal will then be superimposed on the RF signal that drives the acceleration stage A1.

FIG. 2B illustrates schematically an exemplary drive signal 250 that is transmitted to the acceleration stage A1, including a carrier power signal 252 and fingerprint signal 254. Note that the carrier power signal 252 will be coupled to a drift tube electrode (see FIG. 1B) as an RF voltage signal, such as a sinusoidal voltage having a frequency in the MHz range, such as 13.56 MHz, 27.12 MHz or other suitable frequency. The fingerprint signal will represent a higher frequency voltage fluctuation that is superimposed on the MHz sinusoidal wave, for example.

The fingerprint signal 254 may be generated at one or more generation instances. Thus, upon receiving a command signal, such as from a control system (see VCS signal), the gate control and synchronization circuit 204 may generate a fingerprint signal period where the fingerprint signal 254 is to be placed upon an RF power signal at a given generation instance. In other words, in the non-limiting example of FIG. 2B, the fingerprint signal period or duration may be less than the period of the underlying sine wave (e.g. ˜70 ns). Thus, the gate control and synchronization circuit 204 may include a gate element that sets the duration of the fingerprint signal, such as 10 ns. The gate control and synchronization circuit 204 may also have a fingerprint generator (not shown, but see FIG. 3) that generates the specific shape of the fingerprint to be applied during the fingerprint signal period.

According to various embodiments of the disclosure, the fingerprint signal 254 may be generated and incorporated onto an RF signal in a manner that does not unduly perturb operation on the LINAC 118. For example, the fingerprint signal 254 may be crafted so as not to disrupt the resonance in resonators of the LINAC 118, may be designed so as not to change the relative phase of RF signals sent to the different resonators at the respective acceleration stages, and so forth.

At the same time, the gate control and synchronization circuit 204 may generate a time stamp 214 that is transmitted to the fingerprint detection circuit 132. In this embodiment, the fingerprint detection circuit includes a pickup device 220, such as a pickup loop that is coupled to detect the fingerprint signal 254 at a downstream portion of the ion implanter 100, such as at the acceleration stage AN, as shown. In this embodiment, the fingerprint detection circuit 132 include analog-to-digital conversion circuitry, and control circuitry, shown as circuit 222. The circuit 222 may determine the detection instance T2 when the fingerprint signal 254 is received by the pickup device 220. The circuit 222 is also coupled to receive the time stamp 214, including the time stamp as to the generation instance T1. Thus, knowledge of the time-of-flight of the fingerprint signal will lead directly or be indirectly used to determination of the beam energy of the bunched ion beam that was driven by the RF signal carrying the fingerprint signal 254. For example, the fingerprint signal 254 may be placed on an RF signal driving the first acceleration stage, meaning acceleration stage A1, while the fingerprint detection circuit 132 is located at the last acceleration stage of an linear accelerator, where the distance between the first acceleration stage and last acceleration stage is used to help determine the beam energy based on the time-of-flight between T1 and T2.

Note that is this embodiment and other embodiments to follow, the time stamp 214 may be generated at the instance of generation of a fingerprint signal. In other embodiments, the time stamp 214 may be generated as one of a series of time stamps that may be generated at regular intervals, independently of the generation of a fingerprint signal.

In some embodiments, the pickup device 220 may be an inductive or capacitive structure that is located in the beamline of the LINAC 118 to detect/monitor a bunched ion beam as the bunched ion beam traverses through or adjacent to the pickup loop. Thus, the bunched ion beam will generate a signal in such a pickup loop that contains the fingerprint signal 254. In other embodiments, the pickup loop may be a structure, such as an antenna structure that is coupled to detect the fingerprint signal within a resonator of a given acceleration stage.

FIG. 3 shows further details of an exemplary fingerprint signal generation arrangement 300. The fingerprint signal generation circuit 130 may include a gate 303 and a fingerprint generation circuit, shown as a fingerprint generator 304. The gate 303 and fingerprint generator 304, may, in conjunction with synchronization circuit 308, generate a particular fingerprint signal that is amplified at amplifier 206 and transmitted for coupling to an RF power signal via transformer 212.

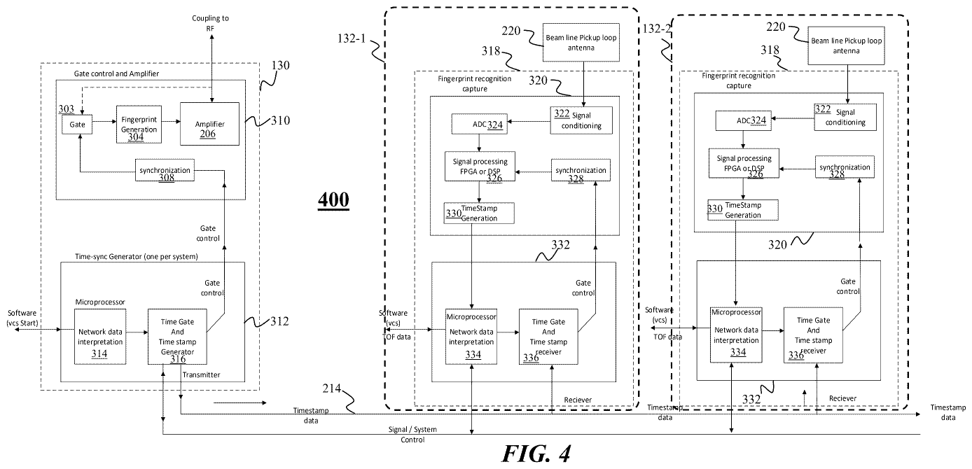

FIG. 4 shows details of an exemplary system shown as beam energy measurement system 400. The beam energy measurement system 400 represents a block diagram the architecture of circuitry for generating and detecting fingerprint signals in a linear accelerator. Certain hardware components, such as RF power supplies, resonators, and drift tube assemblies are omitted for clarity. Note that certain elements of beam energy measurement system 400 may be embodied in any suitable combination of hardware and software. In this embodiment, the fingerprint signal generation circuit 130 includes a gate control circuit 310, to generate the fingerprint signal and couple the fingerprint signal to an RF signal as disclosed above. The gate control circuit 310 includes components as detailed above with respect to FIG. 3. The fingerprint signal generation circuit 130 may also include a time stamp generation circuit, coupled to the gate control circuit, and arranged to generate a time stamp for identifying a generation instance associated with a fingerprint signal produced by fingerprint generator 304. In the embodiment depicted, the fingerprint signal generation circuit 130 further includes a time stamp generation circuit 312, coupled to the gate control circuit 310, and arranged to generate a time stamp for identifying a generation instance associated with a fingerprint signal. In particular, the time stamp generation circuit 312 may include a network data interpretation circuit 314, to receive a command signal, and a time gate and time stamp generator, coupled to the gate control circuit 310. The time gate and time stamp generator 316, upon receiving a command signal from an operating system (OS) via the network data interpretation circuit 314, may generate a gate control signal that is passed to the synchronization circuit 308, and thence, via a synchronization signal, to gate 303, for generating a fingerprint signal. At the same instance, time stamp generator 316 may output a time stamp 214 that identifies the instance when a gate control signal plus control signals are sent. A given one of the fingerprint detection circuit 132-1, fingerprint detection circuit 132-2, is able to identify the instance where a given fingerprint signal is generated.

In other embodiments, the time stamp generator 316 may act independently of the fingerprint generator 304, to generate time stamps at regular intervals. In this manner, the synchronization circuit approximate the instance of the generation of a fingerprint signal by the time stamps that are output nearest in time to the instance of generation of the fingerprint signal by fingerprint generator 304.

In the embodiment of FIG. 4 a plurality of fingerprint detection circuits are illustrated, including fingerprint detection circuit 132-1 and fingerprint detection circuit 132-2. These circuits may contain the same components as one another and may operate similarly to one another. The different fingerprint detection circuits may be coupled to detect a fingerprint signal at different locations of a linear accelerator, and in particular, at different acceleration stages. As shown, each of the fingerprint detection circuits includes pickup device 220, coupled to detect the fingerprint signal at a second acceleration stage, at a second instance, after the instance of generation of the fingerprint signal. The given fingerprint detection circuit also includes a fingerprint capture circuit 318, coupled to the pickup device 220, and arranged to generate a detection time stamp that outputs a time stamp indicative of the second instance.

For convenience, the various components of the fingerprint capture circuit 318 may be arranged into two major sections, shown as fingerprint recognition circuit 320, and fingerprint time stamp circuit 332. A signal conditioning circuit 322 is coupled to receive a signal from the pickup device 220, which device may be a beamline pickup loop antenna in some embodiments. An analog to digital converter 324 may receive the output from the signal conditioning circuit 322, and may output to a signal processing component 326, such as a field programmable gate array or digital signal processor. When the received signal from the pickup device 220 is recognized as the fingerprint signal, a time stamp generator 330 may output the time stamp to a network data circuit 334 that is connected to a control system (not separately shown). The fingerprint time stamp circuit 332 may receive time stamp data from time stamp generator 316, at a time gate and time stamp receiver 336, and may output a signal for the synchronization component 328 that is in turn coupled to the time stamp generator 330

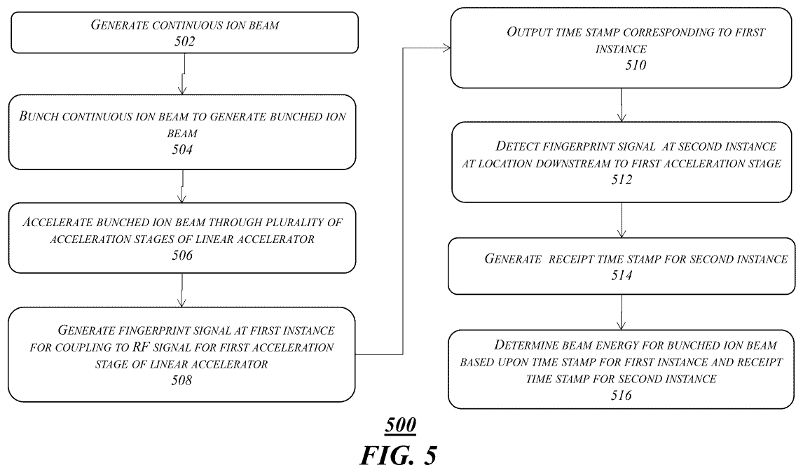

FIG. 5 depicts an exemplary process flow 500 according to some embodiments of the disclosure. At block 502, a continuous ion beam is generated in a beamline ion implanter.

At block 504, the continuous ion beam in bunched into a bunched ion beam for accelerating in an RF linear accelerator. At block 506, the bunched ion beam is accelerated through multiple acceleration stages in the RF linear accelerator.

At block 508, a fingerprint signal is generated at a first instance for coupling to an RF signal that is to be sent to a first acceleration stage of the linear accelerator. In some embodiments, the first acceleration stage may be the most upstream acceleration stage in the linear accelerator. The fingerprint signal may be generated by high frequency circuitry that generates a fingerprint pattern that varies in intensity at a frequency greater than the frequency of the RF signal, so that the RF signal acts as a carrier signal to the fingerprint signal.

At block 510, a time stamp is output corresponding to the first instance when the fingerprint signal is generated.

At block 512, the fingerprint signal is detected at a second location that is downstream to the first acceleration stage. In one example, the second location may be at the position of the most downstream acceleration stage of the linear accelerator. The detection of the fingerprint signal may be performed by a pickup loop antenna positioned in the beamline of the linear accelerator, for example.

At block 514, a receipt time stamp is generated, corresponding to the second instance when the fingerprint signal is detected. The receipt time stamp may be generated by circuitry coupled to a pickup loop detector or other suitable detector.

At block 516, the beam energy for the bunched ion beam is determined based upon the time stamp for the first instance and the receipt time stamp for the second instance.

Referring again to FIG. 1C, there are shown details of a controller 142, arranged to implement the procedures of the present embodiments as set forth above. In one embodiment, the controller 142 may include a processor 144 or multiple processors, such as a known type of microprocessor, dedicated processor chip, general purpose processor chip, or similar device. The controller 142 may further include a memory or memory unit 146, including multiple memory units, coupled to the processor 144, where the memory unit 146 contains a beam energy measurement routine 148. The beam energy measurement routine 148 may be operative on the processor 144 to control the ion implanter 100, and in particular to aid in establishing the proper signals to generate and detect fingerprint signals for the LINAC 118, as well as determining beam energy based upon the detection of the fingerprint signals. Note that according to different embodiments, the controller 142 may be embodied in or coupled to one or more of the aforementioned components, such as in the fingerprint signal generation circuit 130, the fingerprint detection circuit 132, or control system 140.

The memory unit 146 may comprise an article of manufacture. In one embodiment, the memory unit 146 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In view of the foregoing, at least the following advantages are achieved by the embodiments disclosed herein. A first advantage is realized by providing an approach that does not require additional hardware components to add to a beamline to perform beam energy measurement. Another advantage is because in the current approach the beam energy measurement does not disrupt normal operation, such as an ion implantation operation, and can be selected at any time during operation of an implanter with linear accelerator.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implanter, comprising:
an ion source to generate a continuous ion beam; and
a linear accelerator to receive generate a bunched ion beam from the continuous ion beam, and accelerate the bunched ion beam, wherein the linear accelerator comprises:
a plurality of acceleration stages, arranged to accelerate the bunched ion beam to a plurality of energy levels, respectively; and
a beam energy measurement system, arranged to measure a beam energy of the bunched ion beam, after exiting at least one of the plurality of acceleration stages, the beam energy measurement system, comprising:
a fingerprint signal generation circuit, to impart a fingerprint signal into an RF signal to an acceleration stage of the linear accelerator; and
a fingerprint detection circuit, disposed downstream of the acceleration stage, and arranged to detect the fingerprint signal.

2. The ion implanter of claim 1, wherein the acceleration stage is a first acceleration stage, located at a most upstream position in the linear accelerator.

3. The ion implanter of claim 1, wherein the fingerprint detection circuit is coupled to a last acceleration stage, at a most downstream location of the linear accelerator.

4. The ion implanter of claim 1, wherein the fingerprint signal generation circuit comprises:
a gate control circuit, to generate the fingerprint signal and coupled the fingerprint signal to the RF signal; and
a time stamp generation circuit, coupled to the gate control circuit, and arranged to generate a time stamp for identifying a generation instance associated with the fingerprint signal.

5. The ion implanter of claim 4, wherein the time stamp generation circuit comprises:
a network data interpretation circuit, to receive a command signal; and
a time gate and time stamp circuit, coupled to the gate control circuit.

6. The ion implanter of claim 4, wherein the gate control circuit, comprises:
a gate;
a fingerprint generation circuit coupled to the gate;
an amplifier, coupled to receive an output from the fingerprint generation circuit, and to amplify the output for coupling onto the RF signal; and
a synchronization circuit, coupled to receive a gate control signal from the time stamp generation circuit and to output a synchronization signal to the gate.

7. The ion implanter of claim 1, wherein the acceleration stage is a first acceleration stage, where the fingerprint signal is generated at a first instance, wherein the fingerprint detection circuit comprises:
a pickup device, coupled to detect the fingerprint signal at a second acceleration stage, at a second instance; and
a fingerprint capture circuit, coupled to the pickup device, and arranged to generate a detection time stamp that provides a time stamp indicative of the second instance.

8. The ion implanter of claim 1, wherein the fingerprint signal is generated at a generation instance, and is detected at a detection instance, the ion implanter further comprising a controller arranged to determine the beam energy based upon a generation time stamp associated with the generation of the fingerprint signal.

9. The ion implanter of claim 8, wherein the controller is arranged to generate the fingerprint signal at a plurality of generation instances, and wherein the fingerprint detection circuit is arranged to detect the fingerprint signal at a plurality of detection instances.

10. The ion implanter of claim 1,
wherein the acceleration stage is a first acceleration stage,
wherein the fingerprint detection circuit is a first fingerprint detection circuit, disposed at a first location, downstream to the first acceleration stage, and arranged to detect the fingerprint signal at a first detection instance,
wherein the ion implanter further comprises a second fingerprint detection circuit, disposed at a second location, downstream to the first acceleration stage, and arranged to detect the fingerprint signal at a second detection instance.

11. The ion implanter of claim 7, wherein the pickup device is arranged within a beamline enclosure of the linear accelerator to directly measure the bunched ion beam, or is arranged within a resonator of a given acceleration stage of the plurality of acceleration stages.

12. A method of operating an ion implanter, comprising;
generating a continuous ion beam;
bunching the continuous ion beam into a bunched ion beam;
accelerating the bunched ion beam in a linear accelerator that comprises a plurality of acceleration stages;
generating a fingerprint signal at a first instance, for coupling to an acceleration stage of the linear accelerator; and
detecting the fingerprint signal at a second instance, at a detection location, downstream to the acceleration stage.

13. The method of claim 12, further comprising comprises:
at the first instance, coupling the fingerprint signal to an RF signal that is used to accelerate the bunched ion beam at the acceleration stage; and
outputting a generation time stamp for identifying the first instance.

14. The ion method of claim 13, further comprising:
receiving a command signal;
outputting the generation time stamp upon receipt of the command signal; and
outputting a gate control signal to a gate to generate the fingerprint signal, upon receipt of the command signal.

15. The method of claim 14, further comprising:
amplifying the fingerprint signal before coupling to the RF signal.

16. The method of claim 12, wherein the detecting the fingerprint signal comprises:
receiving an RF signal including the fingerprint signal at a pickup device at a second instance; and
generating a detection time stamp that provides a time stamp indicative of the second instance.

17. The method of claim 16, further comprising determining a beam energy of the bunched ion beam based upon the generation time stamp, and the detection time stamp.

18. The method of claim 12, further comprising:
generating the fingerprint signal at a plurality of additional generation instances; and
detecting the fingerprint signal at a plurality of further instances, subsequent to the plurality of additional generation instances, respectively.

19. The method of claim 12,
wherein the acceleration stage is a first acceleration stage,
wherein the detection location is a first detection location,
the method further comprising detecting the fingerprint signal at a third instance, at a second detection location, downstream to the acceleration stage.

20. The method of claim 19, further comprising:
determining a first ion beam energy of the bunched ion beam based upon the detecting the fingerprint signal at the second instance; and
determining a second ion beam energy of the bunched ion beam, based upon the detecting the fingerprint signal at the third instance.
